(19) United States
(12) Patent Application Publication
(10) Pub. No.: US 2026/0218367 A1
(43) Pub. Date: Jul. 30, 2026

(54) METALLIC COMPONENT FOR AQUEOUS ENVIRONMENTS

(71) Applicants: FONDAZIONE ISTITUTO ITALIANO DI TECNOLOGIA, Genova (IT); POLITECNICO DI MILANO, Milano (IT)

(72) Inventors: Fabio DI FONZO, Milano (IT); Mattia CABRIOLI, Vigevano (Pavia) (IT)

(21) Appl. No.: 19/144,661

(22) PCT Filed: Dec. 27, 2023
(86) PCT No.: PCT/IB2023/063279

§ 371 Date: Jun. 30, 2025

(30) Foreign Application Priority Data
Dec. 29, 2022 (IT) 102022000027135

(51) Int. Cl. C23C 14/08

(52) U.S. Cl. CPC C23C 14/083

(57) ABSTRACT

Metallic component for aqueous environments, comprising a body of metallic material and a protective coating applied to an outer surface of the body of zirconium alloy, intended in use to contact an aqueous working fluid, wherein the protective coating includes at least one oxide layer, comprising a matrix oxide and at least one doping element dispersed in the matrix oxide, the matrix oxide being selected from the group consisting of Y2O3, La2O3, SC2O3, Yb2O3, CaO, MgO, Mg2AhO4, or a combination thereof, and the doping element being selected from the group consisting of Ti, V, Cr, Fe, Ni, Cu, Zr, Nb, Sn, Ta, P and oxides thereof.

The present invention relates generally to materials used in aqueous environments, particularly in high-temperature aqueous environments, for example in water-cooled nuclear reactors.

### BACKGROUND OF THE INVENTION

Thermal fission power generation in water-cooled nuclear reactors has the potential to become safer and more efficient, provided accident-tolerant fuels (ATFs) are implemented. The global research and development effort to exploit ATF technology was boosted by the Daichii plant accident in 2011, focusing attention primarily on the inherent limitations of the fuel and cladding materials.

In particular, considering the cladding material, it is necessary to overcome the poor tolerance of zirconium-based alloys (Zircaloys) in terms of resistance to Design Basis (DB) accidents such as the Loss Of Coolant Accident (LOCA). The main issues to be addressed are poor corrosion resistance in water vapor at temperatures equal to or greater than 1200° C., hydrogen absorption in the cladding alloy matrix, and failure under combined mechanical and thermal loads. Additionally, the same material must demonstrate excellent corrosion resistance in liquid or boiling water at temperatures between 270° C. and 360° C. and pressures between 7 MPa and 187 MPa to support the in-core fuel cycle during the normal operation of a light water reactor (LWR). In particular, the case of pressurized water reactors (PWRs) is significant, as the majority of nuclear power plants operating in the world are based on this type of reactor.

In this regard, the best short-term option is to protect the metal cladding by appropriate modification, including coating the cladding with a different material. In the first case, ion implantation was proposed, although no significant improvement was detected. In the second case, various candidates are under study, including nitrides, carbides, oxides and ceramic materials and metals in the MAX phase (pure metal, intermetallic compositions or alloys). Limited investigation has also addressed the effects of multilayer coating structures on corrosion resistance, as an alternative to their single-layer counterpart. The prior art technology is represented by chromium (Cr) coatings manufactured using Cold Spray or Magnetron Sputtering techniques. Such coatings provide zirconium alloys with excellent corrosion resistance for both normal operation and LOCA conditions and wear resistance, at the cost of a small additional disadvantage in terms of the neutron balance of the reactor core.

Despite these advantages, chrome coatings have specific disadvantages that limit the safety thereof in the event of a serious accident. In fact, chromium interacts with the zirconium (Zr) of the cladding tubes at high temperatures (T>800 ° C.), forming an interlayer including the intermetallic composition ZrCr₂ and the eutectic Zr—Cr. The former exhibits brittle behavior which degrades the mechanical properties of the coated cladding, and the latter is responsible for localized melting at 1332° C. (well below the melting point of zirconium alloys ~1800° C.), resulting in simultaneous consumption of both the coating and the cladding material.

For this reason, the potential increase in the maximum allowable temperature and mechanical strength post quenching is limited.

To avoid interdiffusion at the Cr—Zr interface, a suitable diffusion barrier should be designed. Alternatively, it would be possible to choose another material that is compatible with the primary refrigerant of an LWR and resistant to vapor at high temperatures (T>1200 ° C.). The material chosen for the interdiffusion barrier should prevent outward diffusion of Zr from the cladding and inward diffusion of Cr from the cladding. Furthermore, interdiffusion between Zr or Cr and the diffusion barrier material should not be al-lowed. Furthermore, new eutectic reactions of Cr or Zr with the interlayer material should be avoided.

WO 2018067425 A2 and WO2016042262A1 describe the use of an interdiffusion layer of refractory metals, preferably molybdenum (Mo) and tantalum (Ta), respectively. However, Mo and Ta are stronger neutron absorbers than Zr and Cr and would penalize the neutron balance, resulting in an increase in fuel cost.

The use of a Mo layer investigated by CEA and Framatome led to the formation of new interdiffusion layers at the interfaces with Cr and Zr, with possible formation of eutectic with a melting point close to 1332° C., even if the resistance to LOCA events has been increased. Furthermore, Mo oxide is not stable in water and would dissolve in contact with liquid water or evaporate into vapor at high temperature, in case the outer Cr layer was damaged and oxidizing species penetrated the outer coating layer.

The use of a nitride diffusion barrier, in a Cr/CrN multilayer architecture, to prevent Cr—Zr interdiffusion has also been proposed. The formation of the ZrN interlayer at the coating/substrate interface could possibly slow down the diffusion of Cr towards the Zr matrix of the substrate. However, CrN itself is unstable at higher temperatures (T>1000° C.) and subject to decomposition, while each nitride layer, if exposed to the vapor of oxygen-containing species, may be easily oxidized. The consequences of the oxidation reaction and the associated volume change represent a potential problem and a serious limitation for the effectiveness of the nitride barrier concept.

With respect to oxides, the inventors believe that these provide the greatest degree of stability under the combined effects of an oxidizing environment and high temperatures. WO 2020018361 A1 describes a zirconium-based cladding, coated with an intermediate layer formed by ceramic fiber yarn and a first coating, in particular of chromium oxide or niobium oxide, and an outer layer of chromium.

In particular, yttrium oxide (Y₂O₃) has been extensively studied in the field of corrosion protection due to its stability and inertness to different environments. In particular, the application of this material as a corrosion barrier in plasma reactors and solid oxide fuel cell interconnections has been reported. Furthermore, WO 2018017145 A1 and US 2013344348 A1 describe the coating of a zirconium alloy substrate with a corrosion barrier based on oxides, in particular yttrium oxide. In the specific context of ATF-coated cladding, Y₂O₃ would not be reduced by Zr, due to the lower value of its standard free energy of formation. Furthermore, there is no interaction at the interface with Cr. Consequently, during an LOCA event, the thickness of the Cr coating is not decreased by the above-mentioned mechanisms, thus ensuring the protection of Zr from corrosion. At the same time, the formation of new interfaces is hindered, thus preventing the formation of brittle intermetallic compounds. However, in the Y₂O₃—H₂O system at the operating condition for LWR, the yttrium hydroxides Y(OH)₃ and YOOH are considered more stable than Y₂O₃. Therefore, an unprotected layer of pure Y₂O₃ would interact with water to form hydroxides, causing a change in the microstructure of the coating and leading to potential film wear and mechanical failure. On the contrary, Cr in contact with water would form a stable film of Cr₂O₃ which may prevent further oxidation of the underlying layers.

In a broader view, the use of oxide-based ceramics has also been proposed in both cases of corrosion protection in high-temperature water and diffusion barrier at the coating/coating interface. Al₂O₃ and ZrO₂ fabricated as single-layer coatings provided no improvements against high-temperature water, whereas improved corrosion resistance in high-temperature vapor provided by ZrO₂ diffusion barriers in Zr/ZrO₂/FeCrAl systems and Zr/ZrO₂/Cr has only been demonstrated up to 1100° C., still below the reference value for LOCA. Furthermore, since oxygen atoms may be dissolved in the Zr matrix of the fuel cladding, a diffusion process at the Zr/ZrO₂ interface would lead to consumption and reduction of the ZrO₂ layer, allowing degradation of its barrier efficiency and re-exposing the Zr atoms to the external interfaces.

An object of the invention is therefore to provide a coating for metal components, in particular based on a zirconium alloy, which is stable under the normal operating conditions of a water-cooled reactor. Another object of the invention is to provide a coating for metal components, in particular based on zirconium alloy, which may sufficiently resist the extreme conditions that may occur in the event of coolant leak accidents.

### SUMMARY OF THE INVENTION

For the objects indicated above, the subject of the invention is a metallic component for aqueous environments, comprising a body of metallic material and a protective coating applied to an outer surface of the body of metallic material, intended in use to contact an aqueous working fluid,
wherein said protective coating includes at least one oxide layer, comprising a matrix oxide and at least one doping oxide dispersed in the matrix oxide, said matrix oxide being selected from the group consisting of Y₂O₃, La₂O₃, Sc₂O₃, Yb₂O₃, CaO, MgO, Mg₂Al₂O₄, or a combination thereof, and said at least one doping oxide being selected from the group consisting of Ti, V, Cr, Fe, Ni, Cu, Zr, Nb, Sn, Ta, P oxides, wherein said at least one doping oxide comprises:
a single doping oxide, wherein the oxidized element of the single doping oxide is capable of forming a ternary compound with the matrix oxide, and the concentration Ca of the single doping oxide is such that 0.1% mol≤C_{d}<C_{T}, where C_{T} is a maximum value of concentration, defined as the concentration of the single doping oxide in the ternary compound associated to the highest concentration of matrix oxide in the phase diagram matrix oxide-single doping oxide, or
a first doping oxide and at least a second doping oxide, wherein the oxidized element of the first doping oxide is capable of forming a ternary compound with the matrix oxide, and the concentration C_{d} of the first doping oxide is such that 0.1% mol≤C_{d}<C_{T}, where C_{T} is a maximum value of concentration, defined as the concentration of the first doping oxide in the ternary compound associated to the highest concentration of matrix oxide in the phase diagram matrix oxide-first doping oxide,
wherein the concentration of each second doping oxide is lower than or equal to the concentration C_{d} of the first doping oxide.

Furthermore, the object of the invention is a method for producing a metallic component according to the invention, comprising:
depositing said at least one oxide layer onto the alloy body of metallic material by physical vapor deposition, said body of metallic material being kept at a deposition temperature lower than lower than 300° C.

The inventors discovered that doping Y₂O₃ with selected elements improves corrosion resistance during normal operation in a PWR. Furthermore, high temperature experiments conducted by the inventors on the Zr/Y₂O₃/Cr system demonstrated that the diffusion of Zr into Cr and vice versa is prevented at 1200° C. for 1 hour. It is believed that doping may also have a positive effect on the other claimed oxides.

### DETAILED DESCRIPTION OF THE INVENTION

Further features and advantages of the invention will become clearer from the following detailed description of an embodiment of the invention, made with reference to the accompanying drawings, provided purely for illustrative and non-limiting purposes, in which

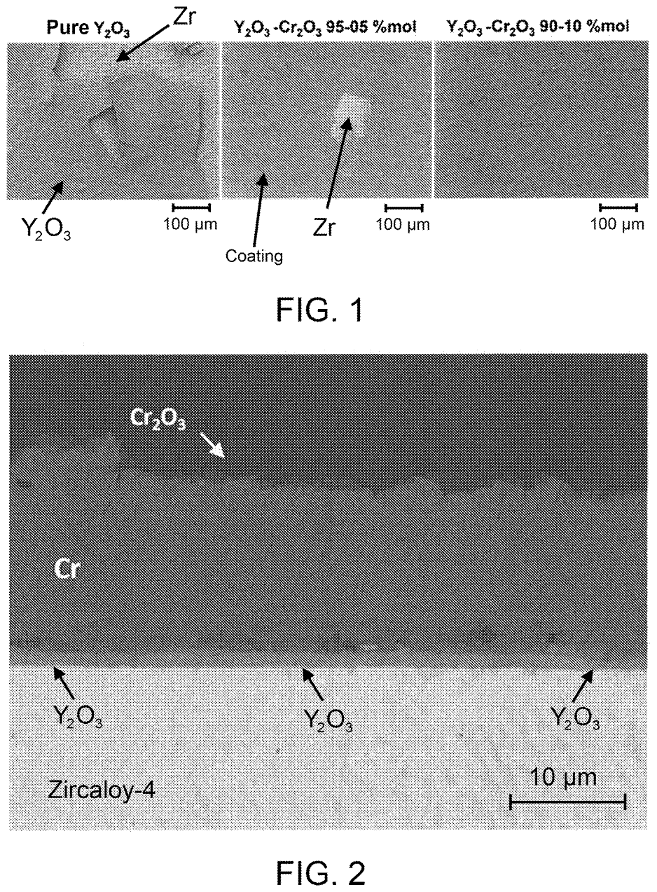

FIG. 1 shows SEM images of samples of Zr sheets coated with pure Y₂O₃ (left panel) and with Y₂O₃ doped with Cr₂O₃ (center and right panels) following exposure to simulated primary coolant of a pressurized water reactor for 14 days in a static autoclave (360° C., saturation pressure, [Li]=2 ppm as LiOH, [B]=1000 ppm as H₃BO₃);

FIG. 2 shows a sectional BSE-SEM image of Zr—4/1 μm Y₂O₃/10 μm Cr following exposure to an Ar flow at 1200° C. for 1h. Inward diffusion of Cr and outward diffusion of Zr are prevented by the presence of the Y₂O₃ layer deposited by PLD on the Zircaloy-4 cladding before the deposition of a thick layer of Cr by magnetron sputtering (MS);

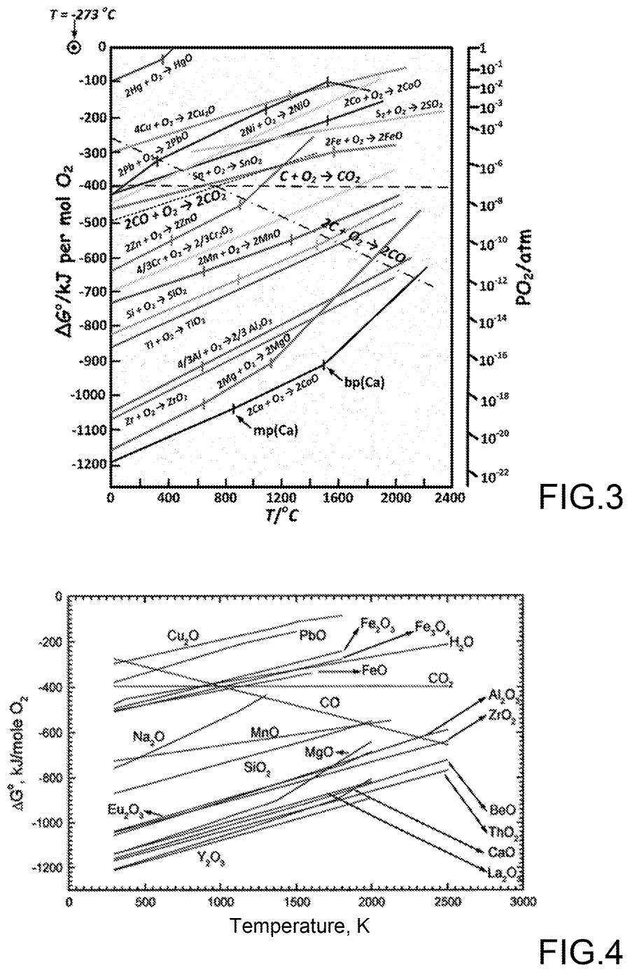

FIGS. 3 and 4 are Ellingham diagrams relating to some oxides (N. N. Greenwood and A. Earnshaw, Chemistry of the Elements, Butterworth-Heinemann, 2nd ed, 1997, ISBN 0080379419; M. Musaddique, A. Rafique (2023) Pyrometallurgy and Electrometallurgy of Rare Earths—Part A: Analysis of Metallothermic Reduction and Its Variants, Mineral Processing and Extractive Metallurgy Review, DOI: 10.1080/08827508.2022.2164576).

A component according to the invention comprises a body of metallic material, in particular of zirconium alloy, with a protective oxide-based coating (deposited in particular by means of the physical vapor deposition [PVD] technique). This component may be, for example, the fuel cladding of nuclear reactors. The protective coating is characterized by a specific chemical composition comprising atoms of suitable dopants included in a matrix of a specific oxide material, consisting of a single layer or a multilayer architecture, or a combination thereof. By virtue of these features, the coating may provide protection to the underlying metal substrate in the environmental conditions typical of the normal operation of a PWR, due to the inherent thermodynamic stability towards water at the temperature and operating pressure of the PWR of a suitable layer in contact with the coolant. Furthermore, the same features that characterize the coating described herein allow the protective capacity to be extended to the typical environmental conditions of LOCA. In this case, the material in contact with the vapor will not be consumed by evaporation or volatilization of the hydroxide species, typically resulting from interaction with water vapor at high temperatures (T>1200 ° C.).

Interactions with Zr from the metal substrate are hindered by the greater thermodynamic stability towards Zr which characterizes the specific oxide which constitutes the matrix of the coating proposed herein.

In a specific formulation, as described in the following paragraphs, the coating may easily be implemented as an interdiffusion barrier layer, to be coated with an outer layer of Cr, with the aim of preventing outward diffusion of Zr and inward diffusion of Cr atoms, as well as the resulting formation of harmful Zr—Cr compounds. According to one embodiment, the oxide-based coating may be made such that it is capable of providing corrosion protection even in the absence of an outer layer consisting of a metal or metal alloy.

The choice of materials is bound by the following criteria:
a. chemical compatibility with water under service conditions for PWRs: the chosen material should form a passive film in pressurized water at a temperature between 270 and 360° C., pH between 6.9 and 7.4, concentration of added elements of [Li+] between 2.2 and 6 ppm, and [10-B] between 1200 and 1800 ppm,
b. limited hydrolization and volatilization in vapor at 1200° C.,
c. stability in contact with Zr in the temperature range from room temperature to the melting point of Zr (1855° C.), thus having a value for the standard Gibbs free energy of formation lower than −1092 kJ/mol,
d. minimization of the differences in thermal expansion coefficient with that of the zirconium alloy (5.8-6.0×10⁻⁶ at room temperature),
e. low absorption cross section for neutrons at thermal energies, otherwise in the range 0.1-4 barn.

Y₂O₃ meets all these criteria except stability in water over the operating parameter range of a PWR (temperature=270-360° C., pH=6,9-7,4, [Li+]=2,2-6 ppm, [10-B]=1200-1800 ppm) whereby the formation of hydroxides is expected. An outer layer of Cr coating, applied over an inner layer of Y₂O₃ may theoretically avoid direct contact between Y₂O₃ and water, but would require very high thicknesses to avoid any pinpoint defects that may cause catastrophic failure of the entire barrier layer, thus exposing the underlying Zr coating. This is undesirable since Cr absorbs more thermal neutrons than Zr or ZrO₂ and therefore requires the nuclear fuel to be enriched in fissile material, to maintain the neutron balance of an uncoated fuel cladding. On the contrary, if the Cr thickness is kept below 10 μm to limit the neutron penalization in the reactor core, the presence of short circuits due to the diffusion of oxidizing species increases due to residual cracks and microholes in the Cr layer. In this case, the interaction of Y₂O₃ and water or OH—groups leads to changes in the microstructure of the diffusion barrier layer, up to the point of mechanical failure and subsequent oxidation of the Zr substrate.

In order to address and mitigate this potential risk, the present invention includes fine-tuning the material properties by introducing suitable doping materials, aimed at improving the overall anti-corrosion and anti-diffusion performance. Suitable material or combinations of materials may be introduced as a dispersion into the material matrix, with uniform concentration along the thickness of the coating. In a particular case, as described in detail below, wherein the coating occurs in a nano-or single-crystalline film structure, the doping element may be preferentially distributed at the grain boundaries. Furthermore, the doping material may be introduced with a concentration varying according to the thickness, with the methods described in detail below.

The invention includes a protective coating composed of at least one ceramic layer, applied to a metal component. The composition of this ceramic layer consists of a dispersion of metal cations of a suitable dopant at the atomic level, in a matrix of a metal oxide. The metal component may be, for example, the cladding of fuel rods for PWR.

The matrix is composed of a metal oxide that may resist reduction by the Zr metal, so the metal oxide is selected from the group comprising Y₂O₃, La₂O₃, Sc₂O₃, Yb₂O₃, CaO, MgO, Mg₂Al₂O₄, or a combination thereof. From the analysis of the neutron absorption cross section for these materials, it is evident that MgO, CaO, Mg₂Al₂O₄ and Y₂O₃ would grant a low penalization in the neutron balance of the reactor core, the penalization introduced by Y₂O₃ being higher than that of MgO, CaO and Mg₂Al₂O₄. On the other hand, the use of La₂O₃, Sc₂O₃, Yb₂O₃ would result in an increasing neutron penalty, since their thermal neutron absorption cross section is 18 to 70 times larger than that of zirconium alloys.

Furthermore, from a thermodynamic point of view, considering MgO, CaO, Mg₂Al₂O₄ and Y₂O₃, the stability of Y₂O₃ against Zr would be the highest. The variation in Gibbs free energy of Y₂O₃ is smaller than that of MgO and CaO over a wide range of temperatures. Furthermore, as the temperature increases, since the slope of the Gibbs free energy variation curve for Zr upon oxidation is lower than that for the formation of Mg₂Al₂O₄, the oxidation curve of Zr would intercept that of formation of Mg₂Al₂O₄. Consequently, there is a temperature for the Zr/Mg₂Al₂O₄ system above which ZrO₂ is thermodynamically favored and Zr would reduce the spinel oxide to Mg and Al metals.

For these considerations, the preferred material for the matrix is Y₂O₃.

Doping elements selected from the group consisting of Ti, V, Cr, Fe, Ni, Cu, Zr, Nb, Sn, Ta, P, are added to increase the stability of the matrix oxide against corrosion and dissolution of the ceramic layer in normal operating conditions or accident conditions of the nuclear reactor. The doping elements are added to the matrix oxide in the form of their more stable oxide. One or more doping elements may be added to the matrix oxide. The elements are selected from those metals that resist dissolution and hydrolysis, possibly forming a passivation layer of their oxide, in the pH and electrochemical potential ranges typical of a primary coolant for PWR.

Since the oxides of the doping elements and the matrix oxide may react to form ternary oxide compounds, the concentration of doping oxide CT characterizing the aforementioned ternary oxide is defined. The doping oxide concentration, denoted Cd, should be less than CT to prevent the growth of a second ternary oxide compound phase within the matrix oxide.

In conclusion, the C_{d} concentration of doping oxide is selected in the range 0.1% mol≤C_{d} <C_{T}. The concentration of the doping oxide C_{d} is preferably selected in the range 5% mol<C_{d}<C_{T}. In a preferred embodiment of the invention, the doping element is Cr and the doping oxide concentration Cr₂O₃ is selected in the range 5% mol<C_{d}<C_{T}, preferably in the range 10% mol≤C_{d}<C_{T}. The ternary oxide compound formed by the reaction of Y₂O₃ with Cr₂O₃ is YCrO₃, and the CT concentration is 50 mol %.

In a preferred embodiment of the invention, the matrix oxide is Y₂O₃, and the metallic element or elements selected as dopants are elements that may form a trivalent ion. Consequently, direct replacement of Y³⁺ions in the matrix oxide does not lead to disruption of the charge balance, for example by the generation of oxygen holes. The low oxygen conduction is an advantage, since the Zr of the substrate material must be protected from oxidation during the entire life cycle of the coated metal component and in the event of an accident. Thus, by doping Y₂O₃ with trivalent cations, there is no possibility of increasing the oxygen conduction of the matrix oxide by the introduction of dopants.

The ceramic layer may have one of the following structures:
1. Matrix oxide in which a uniform dispersion of the doping element along the layer thickness and at the atomic level results in an overall doping oxide concentration, C_{d}, in the range 0.1% mol≤C_{d}<C_{T}, where C_{T} is the doping oxide concentration that characterizes the composition of the ternary oxide compound formed between the matrix oxide and the doping oxide. The C_{d} concentration is preferably within the range 5% mol-20% mol. In a preferred embodiment of the invention, the doping element is Cr and the doping oxide concentration Cr₂O₃ is in the range 5% mol<C_{d}<20% mol, preferably in the range 10% mol≤C_{d}<20% mol. It is worth emphasizing that, with the exception of Nb and Sn, the doping elements listed above are characterized by a larger thermal neutron absorption cross section compared to Y. Aiming at minimizing the penalization introduced by the coating in the neutron balance of the core reactor, the dopant concentration should be limited to the lowest possible value, provided that the resulting composition prevents the interaction between the coating material and the reactor water.
2. A nano or microcrystalline film, in which the doping element is preferentially distributed at the grain boundaries of the matrix-forming oxide. The overall doping oxide concentration, C_{d}, in the range 0.1% mol≤C_{d}<C_{T}, where C_{T} is the doping oxide concentration that characterizes the composition of the ternary oxide compound formed between the matrix oxide and the doping oxide. In a preferred embodiment of the invention, the doping element is Cr and the concentration of the doping oxide, Cr₂O₃, is as reported at point 1 above.
3. Matrix oxide in which a functionally graded concentration of doping oxide varies from a minimum doping oxide concentration Cₘ at the interface with the Zr-based substrate, to a maximum concentration CM on the surface of the coating layer. The concentration values for the doping oxide are such that Cₘ≥0.1% mol and C_{M}<CT.
4. Multilayer in which each layer is composed as the layer described above at point 1. Furthermore, the doping oxide concentration in each layer is increased gradually. The inner layer is characterized by the lowest concentration of dopant Cᵢ≥0.1% mol, and the outer layer is characterized by the highest concentration of dopant Cₒ<C_{T}. The number of layers may be equal to or greater than 2.

The total thickness of the ceramic coating is between 0.1 and 10 μm, with an optimal value between 1 and 5 μm.

In the event that multiple doping elements are present in the matrix oxide, the numerical concentration values provided above refer to the doping element contained in the highest concentration, herein defined as the first doping element. The concentrations of the oxides of the other doping elements will be lower than, or at most equal to, the concentration Cd of the oxide of the first doping element. The concentration values must obviously be such that the sum of the concentration of the matrix oxide with the concentrations of the doping oxides is equal to 100% mol.

The presented coating is capable of withstanding the environmental conditions of an operating nuclear reactor core.

Furthermore, such coating may be used as an interdiffusion barrier in the zirconium alloy/barrier layer/Cr coating system, to prevent the diffusion of Cr towards the Zr matrix and vice versa.

In this case, the coated component consists of a metal component that acts as a support material and a double-layer coating structure. This dual-layer coating includes an inner layer consisting of a ceramic coating as described above, with composition and structure of the coating detailed in cases 1 to 3.

An outer metallic layer is applied over the inner layer, consisting of a metal selected from the group consisting of Cr and Cr-based alloys, for example Cr. The metallic layer is grown on the ceramic layer using physical vapor deposition (PVD) or spray techniques. Examples of PVD techniques are magnetron sputtering and high-power pulsed magnetron sputtering, while an example of a spray technique is cold spray.

The total thickness of the ceramic coating is between 0.01 and 10 μm, with an optimal value between 0.1 and 3 μm. The outer metallic cladding layer, 1-10 μm thick, also has the beneficial effect of improving the long-term stability of the barrier layer upon exposure to the primary coolant during normal reactor operation and under LOCA accident conditions.

The layers of materials described above are grown on zirconium or zirconium alloy sheets or tubes by a physical vapor deposition (PVD) technique, including cathodic arc deposition, magnetron sputtering and pulsed laser deposition (PLD). For example, they may be produced in a PLD system comprising a vacuum chamber and a laser source. The particular PLD process used for coating deposition is carried out without active heating of the substrate. In this case, the temperature of the coated surfaces will always be lower than 300° C., in particular lower than 100° C. Consequently, the microstructural transformation of Zr from α—Zr to β—Zr, which occurs for temperatures above 863° C., is avoided by design. Alternatively, other deposition techniques that involve a temperature of the coated surfaces lower than 300° C. may be used, for example Atomic Layer Deposition (ALD). The layers of ceramic and metallic materials will have a thickness between 1.1 and 20 μm.

In the specific case of coatings produced by PLD, these will be amorphous in structure, with a density greater than 85% of the theoretical density of previous crystalline materials from PLD targets and without any porosity. These combined features may improve barrier efficiency, as no short circuits are created by grain boundaries, porosity, or defects that would otherwise allow oxidizing species or hydrogen to permeate through the coating. The composition of the material, with the presence of appropriate dopants, is capable of providing the following fundamental features:
Stability with Zr at the coating/cladding interface or anti-diffusion barrier/cladding. This feature may be provided by Y₂O₃, whereby the lower value of standard free energy of formation with respect to ZrO₂ will prevent the oxidation of the Zr cladding and the reduction of the Y₂O₃-based coating.
Chemical compatibility with the primary coolant of the PWR core. The composition of the coating is designed to avoid the rapid formation of hydroxides or water-soluble species, which may compromise the integrity of the coating itself.
Low neutron absorption cross section. Zirconium has a cross section for the absorption of thermal neutrons of approximately 0.18 barn, while currently used zirconium alloys absorb thermal neutrons with a cross section of 0.2 barn. The ideal coating layer should have a value equal to or lower than this absorption cross section, in order to minimize the penalization in the neutron balance of the reactor core. However, current candidate materials have absorption cross sections in the range of 2-4 barn. With the present invention it is possible to obtain a material which has a cross section of between 0.5 and 2 barn.

The product described above is versatile and may be used both as an interdiffusion barrier and as a corrosion barrier layer. The compact structure with lower density than Cr and lower thermal neutron absorption cross section will significantly reduce the neutron balance penalization introduced by Cr coatings. In the case of an interdiffusion barrier, the total thickness required for Cr may be reduced to values ranging from tenths of a micron to 5-10 μm, since no interaction with Zr that wears down the coating under LOCA conditions is expected. In the case of replacing Cr as the outer layer, the cross section will be reduced from approximately 3.16 barns to less than 2 barns. In this way, the smaller increase in fuel enrichment to match current performance results in less increase in fuel cost than conventional Cr coatings.

Furthermore, because the Zr matrix remains unaltered by oxidation and interdiffusion mechanisms, the mechanical properties of the coated cladding are preserved during normal operation and LOCA events, until the core emergency cooling systems are activated.

The compatibility of Y₂O₃ with the primary coolant of the pressurized water reactor (PWR) was investigated by exposing PLD-coated Zr samples to the simulated environment of a PWR coolant in a static autoclave.

The effect of single element doping using Cr₂O₃ is shown in FIG. 2. SEM top view analysis revealed that samples coated with pure Y₂O₃ exhibited severe delamination and cracking of the coating, resulting in exposure of the Zr substrate. The addition of doping oxide in the concentration of 5 mol % improved the overall stability of the coating, however, it did not prevent delamination. Finally, when the dopant concentration is increased to 10 mol %, the film is stable and protective.

A demonstration of the effectiveness of Y₂O₃ as a diffusion barrier in the Zr/Y₂O₃/Cr system is shown in FIG. 2. The cross-sectional view of a Zircaloy-4 tube coated with a Y₂O₃/Cr bilayer structure (deposited by PLD and magnetron scattering, respectively), observed with backscattered electron detector to improve compositional contrast, after annealing in argon flowing at 1200° C. for 1 hour, demonstrates that the outward diffusion of Zr from the cladding and the inward diffusion of Cr from the cladding is effectively prevented by the presence of a 1 μm layer of Y₂O₃ deposited via PLD.

More generally, the coating described above may be applied as a protective coating on any metal component for use in aqueous environments at various temperatures, both in liquid and in vapor, as may be easily demonstrated with the Ellingham diagram. As is known, this diagram shows the temperature dependence of the stability of some compounds, such as oxides. In this regard, the Ellingham diagram reports the variation in Gibbs free energy (AG) for each oxidation reaction as a function of temperature. A more negative ΔG value translates into a more thermodynamically favored reaction.

When a pure substance and an oxide come into contact, the oxide is stable only if the AG value is more negative than the possible oxide of the pure substance. Otherwise, the oxide is reduced to the respective pure substance, while an oxide is formed from the other originally pure substance. As may be seen from the Ellingham diagrams of FIGS. 3 and 4, the Zr—ZrO₂ line is found at more negative ΔG values than most oxygen compounds with the other elements of the periodic table, with the exclusion of the rare earths and a few other exceptions.

This in turn results in any oxide being reduced upon contact with Zr as the temperature is increased to overcome kinetic limitations. Even oxides considered to be of maximum stability, such as Al₂O₃ and MgO are reduced to Al and Mg by interaction with Zr.

Y₂O₃, on the other hand, is more stable than ZrO₂ at any temperature, ensuring its stability as a high-temperature barrier layer.

Therefore, a stable oxide barrier on Zr is naturally, or thermodynamically, stable on any other engineering metallic material (such as Fe and steels, Cu, Ti, Mo, W, Ta, Al, Mg, etc.) at any temperature.

1. A metallic component for aqueous environments, comprising a body of metallic material and a protective coating applied to an outer surface of the body of metallic material, intended in use to contact an aqueous working fluid,
wherein the protective coating includes at least one oxide layer, comprising a matrix oxide and at least one doping oxide dispersed in the matrix oxide, the matrix oxide being selected from the group consisting of Y₂O₃, La₂O₃, Sc₂O₃, Yb₂O₃, CaO, MgO, Mg₂Al₂O₄, or a combination thereof, and said the at least one doping oxide being selected from the group consisting of Ti, V, Cr, Fe, Ni, Cu, Zr, Nb, Sn, Ta, P oxides,
wherein the at least one doping oxide comprises:
a single doping oxide, wherein an oxidized element of the single doping oxide is capable of forming a ternary compound with the matrix oxide, and a concentration C_{d} of the single doping oxide is such that 0.1% mol≤C_{d}<C_{T}, where C_{T} is a maximum value of concentration, defined as the concentration of the single doping oxide in the ternary compound associated to a highest concentration of matrix oxide in a phase diagram matrix oxide-single doping oxide, or
a first doping oxide and at least one second doping oxide, wherein an oxidized element of the first doping oxide is capable of forming a ternary compound with the matrix oxide, and a concentration C_{d} of the first doping oxide is such that 0.1% mol≤C_{d}<C_{T}, where C_{T} is a maximum value of concentration, defined as the concentration of the first doping oxide in the ternary compound associated to a highest concentration of matrix oxide in a phase diagram matrix oxide-first doping oxide, and
wherein a concentration of the at least one second doping oxide is lower than or equal to the concentration C_{d} of the first doping oxide.

2. The metallic component according to of claim 1, wherein the concentration C_{d} of the single doping oxide, or of the first doping oxide, is such that 5% mol<C_{d}<C_{T}.

3. The metallic component of claim 1, wherein the concentration C_{d} of the single doping oxide, or of the first doping oxide, is graded along a thickness of the at least one oxide layer, and has a minimum value Cₘ at an interface between the at least one oxide layer and the body of metallic material, and a maximum value C_{M} at an outermost surface of the at least one oxide layer, such that C_{M}>Cₘ.

4. The metallic component of claim 1, wherein the at least one oxide layer comprises an innermost layer and an outermost layer, wherein the concentration C_{d} of the single doping oxide, or of the first doping oxide, in the innermost layer has a minimum value Cᵢ, and the concentration C_{d} of the single doping oxide, or of the first doping oxide, in the outermost layer has a maximum value Cₒ, such that Cₒ>Cᵢ.

5. The metallic component of claim 1, wherein the at least one doping oxide is uniformly dispersed in the at least one oxide layer.

6. The metallic component of claim 1, wherein the matrix oxide is in micro-or nanocrystalline form and the at least one doping oxide is dispersed at grain boundaries of the matrix oxide.

7. The metallic component of claim 1, wherein the matrix oxide is Y₂O₃.

8. The metallic component of claim 7, wherein the single doping oxide, or the first doping oxide, is Cr oxide.

9. The metallic component of claim 1, wherein the protective coating further comprises an outer metallic layer applied to said the at least one oxide layer, said the outer metallic layer being composed of a metal selected from the group consisting of Cr and Cr alloys.

10. The metallic component of claim 1, wherein the metallic component is a cladding tube for nuclear fuel for a water-cooled reactor.

11. The metallic component of claim 1, wherein the metallic material is a zirconium alloy.

12. A method for producing a metallic component for aqueous environments, comprising a body of metallic material and a protective coating applied to an outer surface of the body of metallic material, intended in use to contact an aqueous working fluid,
wherein the protective coating includes at least one oxide layer, comprising a matrix oxide and at least one doping oxide dispersed in the matrix oxide, the matrix oxide being selected from the group consisting of Y₂O₃, La₂O₃, Sc₂O₃, Yb₂O₃, CaO, MgO, Mg₂Al₂O₄, or a combination thereof, and the at least one doping oxide being selected from the group consisting of Ti, V, Cr, Fe, Ni, Cu, Zr, Nb, Sn, Ta, P oxides,
wherein the at least one doping oxide comprises:
a single doping oxide, wherein an oxidized element of the single doping oxide is capable of forming a ternary compound with the matrix oxide, and a concentration Ca of the single doping oxide is such that 0.1% mol≤C_{d}<C_{T}, where C_{T} is a maximum value of concentration, defined as the concentration of the single doping oxide in the ternary compound associated to a highest concentration of matrix oxide in a phase diagram matrix oxide-single doping oxide, or
a first doping oxide and at least one second doping oxide, wherein an oxidized element of the first doping oxide is capable of forming a ternary compound with the
matrix oxide, and a concentration C_{d} of the first doping oxide is such that 0.1% mol≤C_{d}<C_{T}, where C_{T} is a maximum value of concentration, defined as the concentration of the first doping oxide in the ternary compound associated to a highest concentration of matrix oxide in a phase diagram matrix oxide-first doping oxide, and
wherein a concentration of the at least one second doping oxide is lower than or equal to the concentration C_{d} of the first doping oxide,
the method comprising:
depositing the at least one oxide layer onto the body of metallic material by physical vapor deposition or cold spray, the body of metallic material being kept at a deposition temperature lower than 300° C.

13. The method of claim 12, wherein the physical vapor deposition is selected from the group consisting of cathodic arc deposition, magnetron sputtering, atomic layer deposition, and pulsed laser deposition.

14. The method of claim 12, wherein the body of metallic material is kept at a deposition temperature lower than 100° C.
